(19) United States
(12) Patent Application Publication
(10) Pub. No.: US 2007/0045821 A1
(43) Pub. Date: Mar. 1, 2007

(54) Printed circuit board with dual type inner structure

(75) Inventors: Seung-Hyun Cho, Seoul (KR); Han Kim, Daejeon (KR); Soon-Oh Jung, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon-si (KR)

(21) Appl. No.: 11/508,306

(22) Filed: Aug. 23, 2006

(30) Foreign Application Priority Data
Aug. 29, 2005 (KR) 10-2005-0079187

(51) Int. Cl. H01L 23/12

(52) U.S. Cl. 257/704

(57) ABSTRACT

A printed circuit board for inhibiting warpage is disclosed. The printed circuit board has a core layer, which is formed by an insulating material; a circuit pattern layer, which is formed in the upper part of the core layer and has a central area, in which a circuit pattern is formed, and a fringe, which surrounds the central area and is made of a material of high stiffness; an insulating layer, which is formed in the upper part of the circuit pattern layer; and a solder resist, which is formed in the upper part of the insulating layer. The printed circuit board with a dual type inner structure in accordance with the present invention has an effect of inhibiting warpage by having an inner structure in which the rim is made of a material that is hardly warped and a vertex in which the rim is shaped round.

### CROSS-REFERENCE TO RELATED APPLICATIONS

This application claims the benefit of Korean Application No. 10-2005-0079187, filed Aug. 29, 2005, and incorporated by reference herein.

### BACKGROUND OF THE INVENTION

1. Field of the Invention

The present invention is related to a substrate, more specifically to a printed circuit board and a method thereof.

A printed circuit board refers to a silicon substrate on which a semiconductor chip is mounted by use of flip chip bonding or wire bonding. Hereinafter, a flipchip ball grid array (“flip chip BGA” hereinafter), which is commonly applied to a CPU and a graphic card, will be described.

In a conventional method, a chip is adhered to a lead frame, and the pad and terminal of the chip are connected with a bonding wire before being sealed with resin. This type of package had to be large and heavy, and the wiring had to be lengthy. The flip chip BGA package is developed to solve this problem by adhering a chip to an epoxy or ceramic substrate and using a round solder ball as the terminal. The flip chip BGA substrate has a warpage due to the head applied during the manufacturing process, and the defect of not being able to mount the chip is inevitable if the warpage is great. Moreover, although a flip chip BGA substrate passes the warpage test, the high heat generated during the mounting of the chip causes a warpage, and a large warpage results in the defect of the chip and substrate separating.

For the latest flip chip BGA substrates that have become increasingly ultra-thinner, the thickness of the core has to be as thin as 0.1 mm or 0.2 mm. This thinness of the core thickness will inhibit the development of the ultra-thin flip chip BGA unless the warpage problem is solved.

It can be contrived that a highly stiff core material be developed in order to make the flip chip BGA thinner, but increasing the stiffness of the core alone cannot solve the warpage problem because the corner of a flip chip BGA still warps due to the non-linear behavior of a polymer, that is, the phenomenon of warping to a certain direction and shape at a certain temperature. Besides, using a highly stiff material, such as steel, lowers the adhesion to the insulating material, possibly causing the separation and the cost increase.

2. Discussion of the Prior Art

FIG. 1 is a perspective view of a normal FCB of a printed circuit board in accordance with the prior art, and FIG. 2 is a perspective view of a warped FCB of a printed circuit board in accordance with the prior art.

Referring to FIG. 1, a chip is mounted on the surface of the flip chip BGA. FIG. 2 illustrates the fringe and corner of the flip chip BGA wound up higher than the center, in which the chip is mounted.

FCB substrates usually have a rectangular shape, as seen in FIG. 1. In the case of a multilayer substrate, a metal (e.g. copper) pattern is evenly distributed in symmetry above and below the core layer. The most common thickness of the core is currently 0.8 mm. However, with the technological development, which allows the core to be thinner and smaller, the ultra thin flip chip BGA (“UTFCB” hereinafter) is also becoming even thinner. The conventional flip chip BGA substrate becomes a concave shape on the opposite side of the chip, due to the heat applied during the manufacturing process. When the core thickness is reduced to 0.4 mm in order to make a UTFCB, the thermal deformation increases to roll the corners, as shown in FIG. 2. This kind of thermal deformation inhibits the UTFCB from becoming thinner.

Therefore, in order to develop a UTFCB with much less warpage, it is imperative to develop a core material with much enhanced stiffness and modify the inner structure.

### SUMMARY OF THE INVENTION

The present invention provides a printed circuit board with a dual type inner structure that can inhibit the warpage in a certain direction by constructing a dual type inner structure in a printed circuit board. In other words, a printed circuit board with a dual type inner structure that can inhibit the warpage in a certain direction is provided by forming the fringe of the inner structure of a printed circuit board with a material that hardly warps and by making the fringe of the vertex of a printed circuit board a round shape.

Moreover, the present invention provides a printed circuit board with a dual type inner structure that can inhibit the warpage of the substrate by modifying the inner structure of an ultra thin flip chip BGA substrate having a core thickness of 0.1 mm and 0.2 mm.

Furthermore, the present invention provides a printed circuit board with a dual type inner structure that does not require a separate process to reduce the warpage, by making the inner structure a dual type, thereby reducing the time and cost of additional processes for the reduction of warpage.

An aspect of the present invention features a printed circuit board for inhibiting warpage. The printed circuit board has a core layer, a circuit pattern layer, an insulating layer and a solder resist. The core layer is formed by an insulating material. The circuit pattern layer, formed in the upper part of the core layer, has a central area and a fringe. A circuit pattern is formed in the central area. The fringe, surrounding the central area, is made of a material of certain stiffness, which is the same as or higher than the stiffness of a material used in the circuit pattern. The insulating layer is formed in the upper part of the circuit pattern layer. The solder resist is formed in the upper part of the insulating layer.

Here, the core layer can be stacked with a plurality of the circuit pattern layers and insulating layers.

Here, the fringe can be made of metal, and especially, the fringe can be made of copper.

The corner of the fringe can be a round shape.

The part where the insulating layer comes in contact with the fringe can be made of the same material as the fringe.

The fringe can surround the central area around the rim of the central area.

Another aspect of the present invention features a method for forming a printed circuit board for inhibiting warpage. The method comprises the steps of (a) forming a core layer using an insulating material; (b) forming a circuit pattern layer, the circuit pattern layer forming in the upper part of said core layer, the circuit pattern layer comprising a central area and a fringe, a circuit pattern forming in the central area, the fringe surrounding the central area, the fringe being made of a material of a stiffness, the stiffness being the same as or higher than a stiffness of a material used in said circuit pattern; (c) forming an insulating layer, the insulating layer forming in the upper part of said circuit pattern layer; and (d) forming a solder resist, the solder resist forming in the upper part of said insulating layer.

Here, the steps (b) and (c) can be repeated a predetermined number of times.

Here, the fringe can be made of metal, and especially, the fringe can be made of copper.

The corner of the fringe can be a round shape.

In the above step (c), the part where the insulating layer comes in contact with the fringe can be made of the same material as the fringe.

The fringe can surround the central area around the rim of the central area.

Here, the width of the fringe can be 0.1 mm or 0.2 mm.

The printed circuit board can be a flip chip BGA.

### BRIEF DESCRIPTION OF THE DRAWINGS

These and other features, aspects, and advantages of the present invention will become better understood with regard to the following description, appended claims, and accompanying drawings where:

FIG. 1 shows a perspective view of an FCB of a printed circuit board in accordance with the prior art;

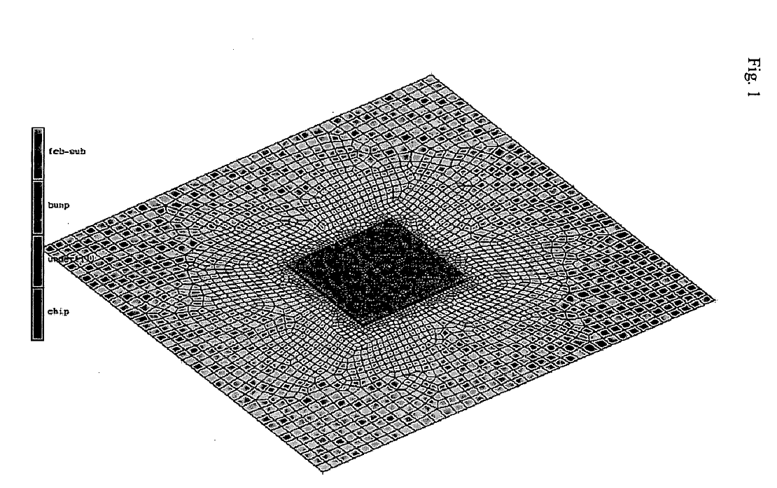

FIG. 2 shows a perspective view of a warped FCB of a printed circuit board in accordance with the prior art;

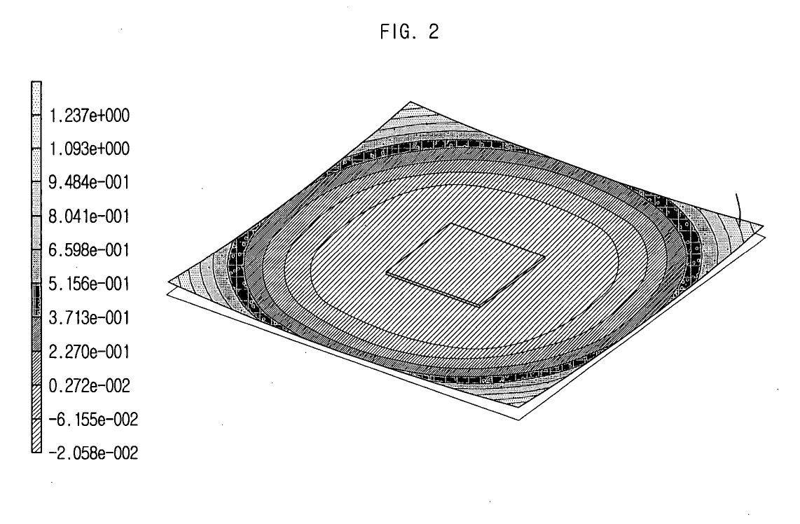

FIG. 3 shows a top plan view of a printed circuit board with a dual type inner structure in accordance with a preferred embodiment of the present invention;

FIG. 4 is a sectional view of the center of a printed circuit board with a dual type inner structure in accordance with a preferred embodiment of the present invention;

FIG. 5 shows a sectional view of the fringe of a printed circuit board with a dual type inner structure in accordance with a preferred embodiment of the present invention;

FIG. 6 compares the distribution of deformation between a printed circuit board of the prior art and a printed circuit board with a dual type inner structure in accordance with a first embodiment of the present invention;

FIG. 7 compares the distribution of deformation between a printed circuit board of the prior art and a printed circuit board with a dual type inner structure in accordance with a second embodiment of the present invention; and

FIG. 8 shows a graph illustrating the improvement of deformation between a printed circuit board of the prior art and a printed circuit board with a dual type inner structure in accordance with a preferred embodiment of the present invention.

### DETAILED DESCRIPTION OF THE INVENTION

Hereinafter, preferred embodiments of a printed circuit board with a dual type inner structure in accordance with the present invention will be described by making reference to the accompanying drawings. In referencing the accompanying drawings, the same reference numerals will be used for the same elements, regardless of the figure number, and the pertinent description for the same element will not be repeated. Before describing preferred embodiments of the present invention in detail, the manufacturing methods for a general substrate and a flip chip BGA, respectively, will be described. Although the manufacturing method for a multilayer substrate will be described, the present invention is by no means restricted to a method for manufacturing a multilayer substrate.

In order to manufacture a printed circuit board, an internal circuit pattern is formed outside the core layer. Here, a predetermined internal circuit pattern is formed by cutting an inner layer material that meets the product specification and by using a dry film and a working film. Here, the inner layer can be scrubbed, the inner layer dry film can be laminated, and the inner exposure/development process can be performed.

Then, prior to adhering the inner layer, on which a circuit pattern is formed, to the outer later, a process, such as brown (or black) oxide process, to enhance the adhesion is performed. That is, the surface of the copper foil is chemically oxidized to enhance the surface luminance such that the stacking adhesion is securely made. Then, the pre-stacking and stacking processes are performed by stacking the inner substrate and prepreg.

Later, the stacked inner substrate and prepreg are vacuum-pressed. Here, it is possible to hot-press for a predetermined duration at a high temperature and cool-press the hot-pressed substrate, instead of vacuum-pressing.

A trimming process is performed to trim the resin and copper foil on the corner of the panel, and an X-ray target drill process is performed to drill a hole on a target guide mark on the inner layer circuit.

Later, a drilling process of drilling a hole for electrical conduction between the substrate layers is performed. Here, the drilling process can be a CNC (computer numerical control) method, which drills necessary holes on the substrate.

Later, the outer layer is laminated with a dry film and a working film to form a circuit pattern, and is irradiated with a predetermined intensity for a predetermined duration, and any unirradiated areas are developed in an etching process. After testing the outer layer and measuring the scale, a solder resist exposure film is designed and manufactured. Then, the solder resist process is pre-treated by making the copper surface rough such that the solder resist ink is better adhered to the substrate. Here, the pre-treatment process can be a brush polishing process. Then, the solder resist is laminated, a solder resist exposure process is performed using the solder resist exposure film, which was adaptively designed in the earlier process, and a development process, in which the solder resist ink is removed, is performed. Moreover, various post-treatment processes, including the surface treatment and electrical/final test, are performed.

The manufacturing processes of a flip chip BGA package is generally as follows:

(a) An aluminum pad is formed on a semiconductor chip, on which a protective layer is then covered. (b) Using a sputtering process, a metal layer is formed and is contacted to the pad. (c) The metal layer is laminated with photo resist such that only the pad area is exposed. (d) Lead is plated on the pad area where photo resist is exposed. (e) The photo resist is removed. (f) The metal foil on the area of other than the lead plated area is etched out. (g) The plated lead is heated and processed to make it round. (h) The bump chip manufactured through the above process is coupled to a flip chip BGA substrate. For the coupling method, the substrate is inserted in a reflow device before the substrate is heated at a high temperature such that the plated lead is melted to couple the contact pad of the flip chip BGA substrate and the pad of the chip. Then, through the underfill process, resin is filled in between the above flip chip BGA substrate and the above chip.

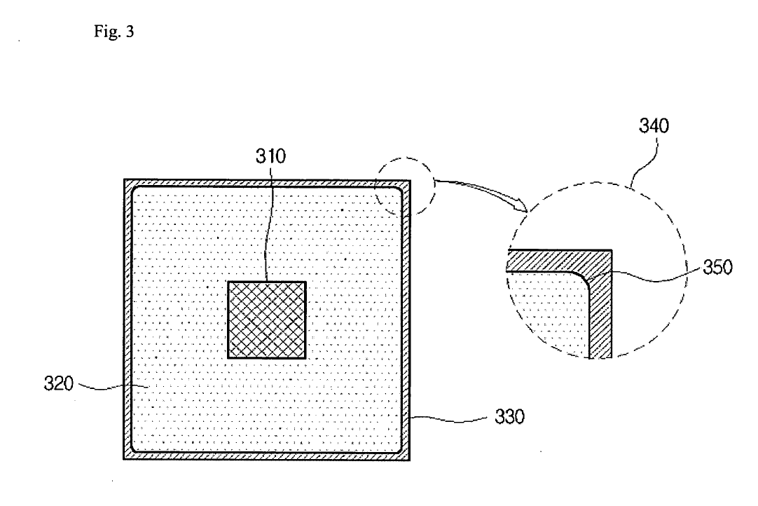

FIG. 3 is a top plan view of a printed circuit board with a dual type inner structure in accordance with a preferred embodiment of the present invention. Referring to FIG. 3, a printed circuit board with a dual type inner structure in accordance with the present invention comprises a semiconductor chip 310, a central area 320, a fringe 330, a corner 340 and a round-type corner 350.

Here, the printed circuit board can be a flip chip BGA substrate or a substrate used in a BOC (board on chip), a CSP (chip scale package) or a UTFCB (ultra thin flexible circuit board). The printed circuit board can ba any of the single-layer substrate, double-layer substrate and multi-layer substrate. Here, the printed circuit board can be formed in 4 layers, 6 layers, 8 layers or a higher number of layers.

The semiconductor chip 310 is in contact with the substrate by flip chip bonding. A variety of contacting technologies, including wire bonding using a conductive metal wire, TAB (tape automated bonding) using a tape circuit substrate and flip chip bonding using a conductive material bump to directly mount a semiconductor chip on a substrate, are known. Among these, the flip chip bonding is widely used in the fabrication of semiconductor chip packages recently due to its relatively higher speed, higher density and smaller size over other contacting technologies. In general, the semiconductor chip for flip chip bonding and its mounting structure are as follows:

The semiconductor chip 310 used in flip chip bonding has a structure in which a conductive material bump, for example, a ball-type solder bump, is formed by being in contact with an electrical pad. In the upper part of the semiconductor substrate, an electrical pad, of aluminum or copper material, is formed for electrical connection with outside. The electrical pad is exposed and is covered with a passivation layer. The solder bump is formed in the upper part of the exposed electrical pad, and the multilayer UBM (under barrier metallurgy) is formed in between the solder bump and the electrical pad.

The UBM, formed on the electrical pad, can include a barrier metal layer, which functions to prevent diffusion such that the solder component of the solder bump is kept from penetrating into the electrical pad and semiconductor substrate, and a solder welting layer, which is formed over the metal layer to help the solder bump make a better contact.

This semiconductor chip 310 for flip chip bonding is electrically connected and physically coupled by joining the solder bump and the substrate contact pad, which is prepared on the substrate of the printed circuit board. Generally, underfill resin is filled in between a semiconductor chip 310 and a printed circuit board to protect the joined area from outside, improving the reliablity of interconnection.

The central area 320 has a circuit pattern, typically formed on a printed circuit board. In other words, a predetermined circuit pattern is formed on the printed circuit board such that the semiconductor chip 310 can be electrically connected.

The fringe 330, made of a particular material, is connected throughout the circumference of the central area 320. Here, since the fringe 330 is made of a connected, identical material, the warpage of the prior art can be reduced. In case the fringe 330 is made of the same material as the circuit metal formed on the center 320, it can be formed simultaneously during the process of forming the circuit pattern in the printed circuit board manufacturing process. For instance, if the circuit pattern formed in the center 320 is made of copper, the fringe 330 can be formed with copper, in which case the fringe 330 can be formed in the same process as the circuit pattern forming process, thereby eliminating the need for a separate process. Here, the width of the fringe 330 can be determined according to the overall size and thickness of the substrate, preferably being 0.1 mm or 0.2 mm.

The corner 340 is where the sides formed by the fringe 330 meet. Here, the area 350 where the corner 340 meets the central area 320 can be a round shape. When the corner 340 is round, the warpage of the overall printed circuit board can be reduced. That is, since the warpage of a printed circuit board usually emanates from the semiconductor chip 310, making the central area 320 as round as possible can reduce the warpage of the overall printed circuit board. Therefore, in case the corner 340 is round, the amount of warpage of the printed circuit board can be reduced. Here, the width of the corner 340 and the curvature of the round shape can be determined in accordance with the overall size and thickness of the substrate, preferably being 0.1 mm or 0.2 mm.

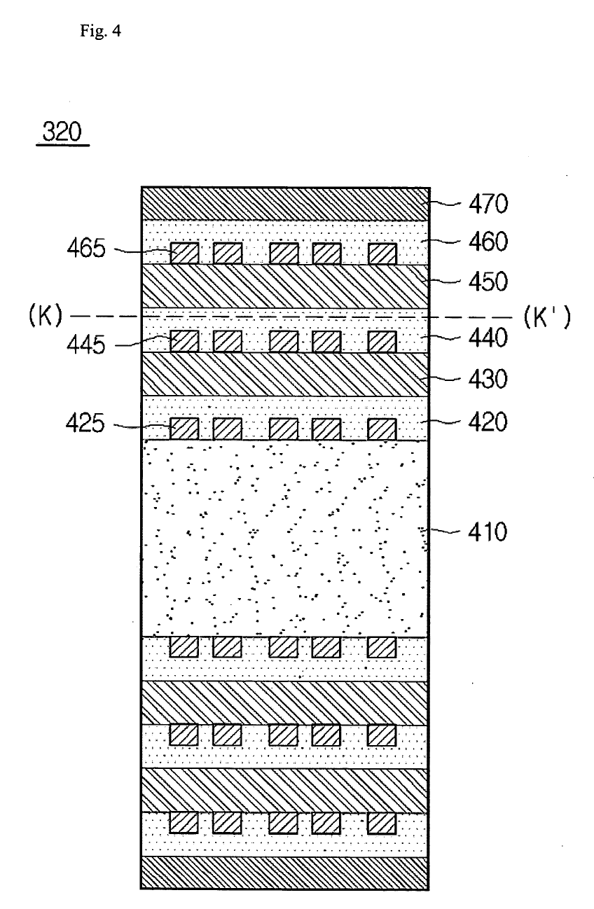

FIG. 4 is a sectional view of the center 320 of a printed circuit board with a dual type inner structure in accordance with a preferred embodiment of the present invention. Referring to FIG. 4, the printed circuit pattern in accordance with the present invention can comprise a core layer 410, a first circuit pattern layer 420, a first circuit pattern 425, a first insulating layer 430, a second circuit pattern layer 440, a second circuit pattern 445, a second insulating layer 450, a third circuit pattern layer 460, a third circuit pattern 465 and a solder resist 470.

The first circuit pattern layer 420 has the first circuit pattern 425, the second circuit pattern layer 440 the second circuit pattern 445, and the third circuit pattern layer 460 the third circuit pattern 465. The sectional view along the (k)-(k′) line indicates the central area 320 shown in FIG. 3. The circuit pattern is symmetrically formed about the core layer 410. Although the overall printed circuit board is made up of 6 layers, as in FIG. 4, it should be evident that the number of layers is not restricted to what is shown in the present invention.

Here, the overall printed circuit board includes the central area 320, in which the circuit pattern layer is alternately stacked with the insulating layer, and the fringe 330, in which, interconnected and made up of a particular material, the layer surrounding the central area 320 is alternately stacked with the insulating layer. Moreover, each circuit pattern layer includes a central area, in which a circuit pattern is usually formed, and a fringe, in which a same material is continuously formed to surround the central area. Here, the fringe formed on each circuit pattern layer can be formed on the rim, which is the border of the printed circuit board, or can be formed by surrounding each central area if the central area is formed in various locations. That is, if the semiconductor chip is formed as a group to be mounted in a printed circuit board, each group can form a central area. In this case, a plural number of fringes can be formed to surround each central area, in order to improve the warpage of each central area.

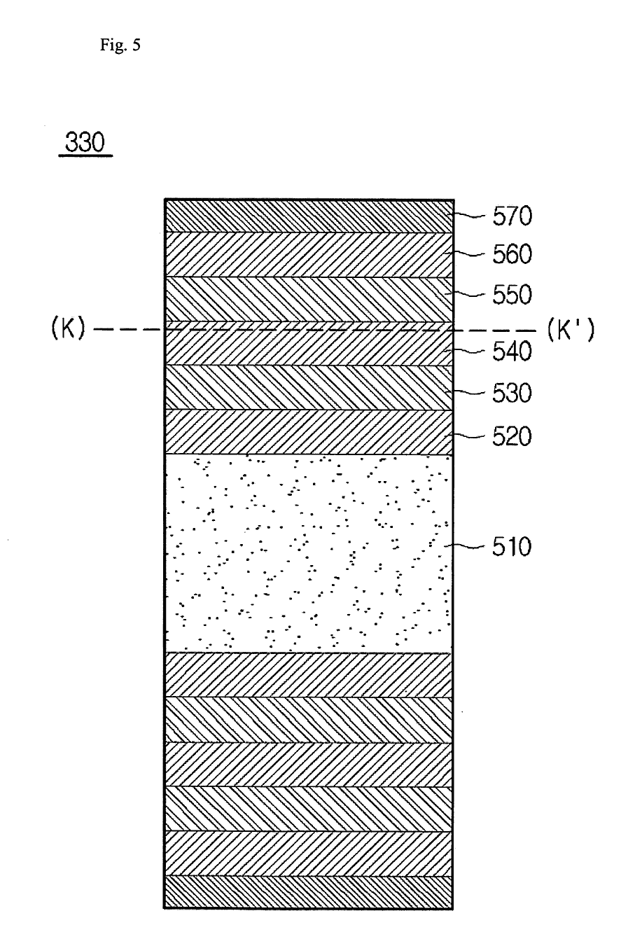

FIG. 5 shows a sectional view of the fringe 330 of a printed circuit board with a dual type inner structure in accordance with a preferred embodiment of the present invention. Referring to FIG. 5, the printed circuit board in accordance with the present invention can comprise a core layer 510, a first circuit pattern layer fringe 520, a first insulating layer 530, a second circuit pattern layer fringe 540, a second insulating layer 550, a third circuit pattern layer fringe 560 and a solder resist 570.

The fringe 330 of a printed circuit board in accordance with the present invention does not have a layer, in which a separate circuit pattern is formed, of the prior art, but has the fringe of a circuit pattern layer that is formed continuously to surround the central area. The fringe 520, 540, 560 of each circuit pattern can be of a material of high stiffness and little warpage, more specifically can be copper, which is the metal that forms the circuit. In other words, in case the fringe 520, 540, 560 is made of copper, which is commonly used to form a circuit pattern, the forming process can be easier. Moreover, the fringe can be formed with a material that is stiffer than the metal used in the circuit pattern, if much improvement in warpage is desired. Here, for a stiffer, thereby resulting in less warpage, material, an aluminum oxide metal, a titanium carbide metal or a hard metal (tungsten carbide) metal can be used.

In another embodiment, the fringe 330 of a printed circuit board in accordance with the present invention can have all layers that are made of the same material. For example, the insulating layer 530, 550 can be formed with the same material as the fringe 520, 540, 560 of the circuit pattern layer to prevent the warpage of the printed circuit board. For this, the fringe 330 can be formed simultaneously while forming each layer if a separate process of forming the fringe 330 is added, or an ink jet is used to form the printed circuit board.

So far, sectional views that generally show a printed circuit board with a dual type inner structure have been described. Hereinafter, actual test results of printed circuit boards with a dual type inner structure in accordance with the present invention will be described. The test results that will be described below have been obtained through the simulation application MSC/MARC.

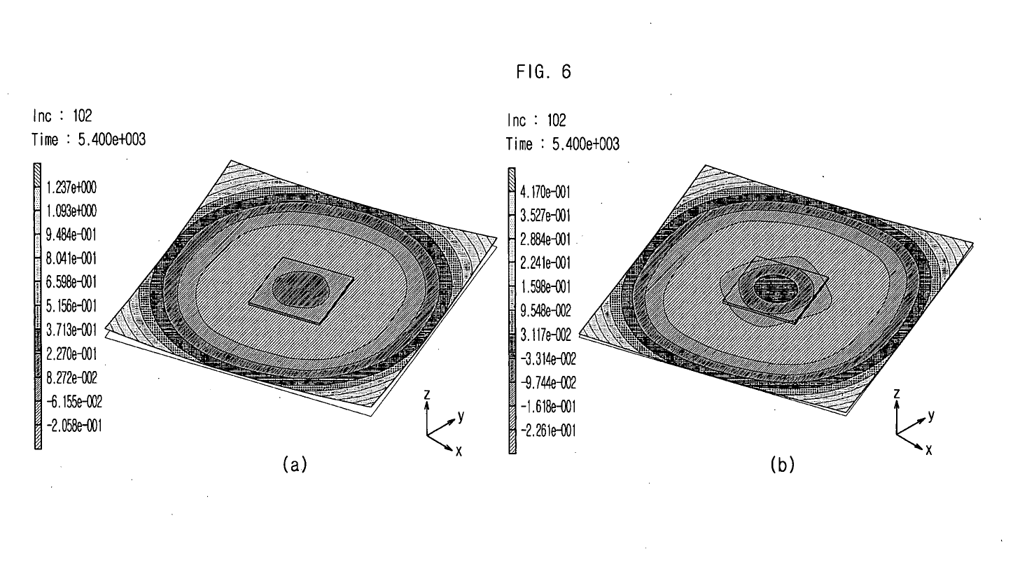

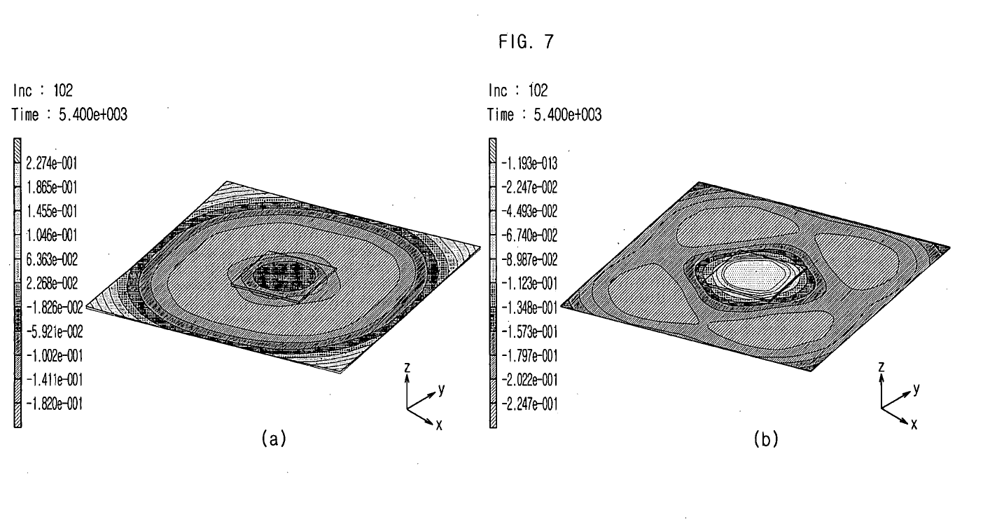

FIG. 6 compares the distribution of deformation between a printed circuit board of the prior art and a printed circuit board with a dual type inner structure in accordance with a first embodiment of the present invention. FIG. 7 compares the distribution of deformation between a printed circuit board of the prior art and a printed circuit board with a dual type inner structure in accordance with a second embodiment of the present invention. Here, the thickness of the core used in the first embodiment is 0.1 mm, and the thickness of the core used in the second embodiment is 0.2 mm. The direction of warpage is specified as the z-axis.

The corner rolling of the flip chip BGA using the core thickness of 0.8 mm was minute, but reducing the core thickness to 0.4 mm caused a significant corner rolling, increasing the amount of warpage.

In order to observe the warpage inhibition effect, the simulation was carried out while the temperature was lowered from 175 degrees to 25 degrees. Referring to FIG. 6, the baseline flip chip BGA had a dimension of 37.5×37.5 mm, core thickness of 0.1 mm and a 6-layer structure. A flip chip BGA substrate in accordance with the prior art is shown in (a), and a flip chip BGA substrate in accordance with the present invention is shown in (b). It shows the distribution of warpage produced by the inner copper pattern of the core thickness of 0.1 mm, and it can be inferred that making the inner layer of the FCB rim with copper only significantly reduced the warpage. That is, referring to the numerical value of warpage, the flip chip BGA substrate (a) of the prior art is warped from −2.058e⁻⁰⁰¹ mm to 1.237 mm. On the other hand, the flip chip BGA substrate (b) of the present invention is warped from −2.261e⁻⁰⁰¹ mm to 4.170e⁻⁰⁰¹ mm. As shown in this comparison, the flip chip BGA substrate (b) of the present invention was less warped than the flip chip BGA substrate (a) of the prior art.

Referring to FIG. 7, the distribution of warpage produced by the inner core pattern of the core thickness of 0.2 mm is illustrated. A flip chip BGA substrate in accordance with the prior art is shown in (a), and a flip chip BGA substrate in accordance with the present invention is shown in (b). Referring to the numerical value of warpage, the flip chip BGA substrate (a) of the prior art is warped from −1.820e⁻⁰⁰¹ mm to 2.274e⁻⁰⁰¹ mm. On the other hand, the flip chip BGA substrate (b) of the present invention is warped from −2.247e⁻⁰⁰¹ mm to −1.193e⁻⁰¹³ mm. As shown in this comparison, the flip chip BGA substrate (b) of the present invention was less warped than the flip chip BGA substrate (a) of the prior art.

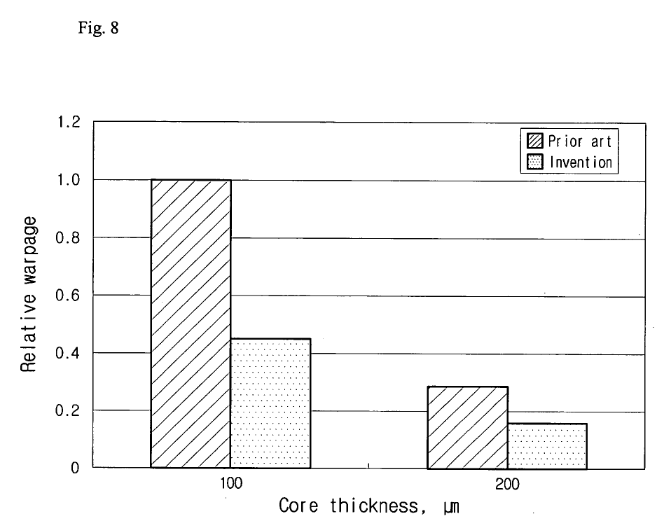

FIG. 8 shows a graph illustrating the improvement of deformation between a printed circuit board of the prior art and a printed circuit board with a dual type inner structure in accordance with a preferred embodiment of the present invention. That is, FIG. 8 compared the warpage between an embodiment of the present invention, in which the rim of the inner structure is made of copper, and a model with a conventional inner structure (copper pattern). The comparison was based on the core thickness of 0.1 mm and an FCB with the conventional inner structure (copper pattern). The bars on the left side of the graph are for the core thickness of 0.1 mm while the bars on the right side are for the core thickness of 0.2 mm.

Referring to FIG. 8, in the case of the core thickness of 0.1 mm, when the warpage of a flip chip BGA substrate in accordance with the prior art is set as 1, the flip chip BGA substrate in accordance with the present invention is about 0.4. Therefore, according to the present invention, the warpage is reduced by about 125% when the core became as thin as 0.1 mm.

Furthermore, in the case of the core thickness of 0.2 mm, when the warpage of the flip chip BGA substrate in accordance with the prior art is set as 0.3, the flip chip BGA substrate in accordance with the present invention is about 0.15. Therefore, according to the present invention, the warpage is reduced by about 82% when the core became as thin as 0.2 mm.

The present invention is not restricted to the above embodiments, and a large number of permutations are possible within the spirit and scope of the present invention by anyone of ordinary skill in the art the invention pertains.

From the foregoing, the printed circuit board with a dual type inner structure in accordance with the present invention can inhibit the warpage in a certain direction by constructing a dual type inner structure in a printed circuit board. In other words, the present invention can inhibit the warpage in a certain direction by forming the fringe of the inner structure of a printed circuit board with a material that hardly warps and by making the fringe of the vertex of a printed circuit board a round shape.

Moreover, the printed circuit board with a dual type inner structure in accordance with the present invention can inhibit the warpage of the substrate by modifying the inner structure of an ultra thin flip chip BGA substrate having a core thickness of 0.1 mm and 0.2 mm.

Furthermore, the printed circuit board with a dual type inner structure in accordance with the present invention does not require a separate process to reduce the warpage, by making the inner structure a dual type, thereby reducing the time and cost of additional processes for the reduction of warpage.

Although preferred embodiments of the present invention have been described above, those who have ordinary skill in the art the invention pertains should be able to understand that the present invention can be modified and permutated in various ways without departing the spirit and scope of the invention and its equivalents.

What is claimed is:

1. A printed circuit board for inhibiting warpage, the printed circuit board comprising:
a core layer, the core layer formed by an insulating material;
a circuit pattern layer, the circuit pattern layer forming in the upper part of said core layer, the circuit pattern layer comprising a central area and a fringe, a circuit pattern forming in the central area, the fringe surrounding the central area, the fringe being made of a material of certain stiffness, the stiffness being the same as or higher than the stiffness of a material used in said circuit pattern;
an insulating layer, the insulating layer forming in the upper part of said circuit pattern layer; and
a solder resist, the solder resist forming in the upper part of said insulating layer.

2. The printed circuit board of claim 1, wherein said core layer is stacked with a plurality of said circuit pattern layers and insulating layers.

3. The printed circuit board of claim 1, wherein said fringe is made of metal.

4. The printed circuit board of claim 1, wherein said fringe is made of copper.

5. The printed circuit board of claim 1, wherein the corner of said fringe is a round shape.

6. The printed circuit board of claim 1, wherein the part where said insulating layer comes in contact with said fringe is made of the same material as said fringe.

7. The printed circuit board of claim 1, wherein said fringe surrounds said central area around the rim of said central area.

8. The printed circuit board of claim 1, wherein the width of said fringe is 0.1 mm or 0.2 mm.

9. The printed circuit board of claim 1, wherein said printed circuit board is a flip chip BGA.

10. A method for forming a printed circuit board for inhibiting warpage, the method comprising the steps of:
(a) forming a core layer using an insulating material;
(b) forming a circuit pattern layer, the circuit pattern layer forming in the upper part of said core layer, the circuit pattern layer comprising a central area and a fringe, a circuit pattern forming in the central area, the fringe surrounding the central area, the fringe being made of a material of certain stiffness, the stiffness being the same as or higher than the stiffness of a material used in said circuit pattern;
(c) forming an insulating layer, the insulating layer forming in the upper part of said circuit pattern layer; and
(d) forming a solder resist, the solder resist forming in the upper part of said insulating layer.

11. The method of claim 10, wherein said steps (b) and (c) are repeated a predetermined number of times.

12. The method of claim 10, wherein said fringe is made of metal.

13. The method of claim 10, wherein said fringe is made of copper.

14. The method of claim 10, wherein the corner of said fringe is a round shape.

15. The method of claim 10, wherein in said step (c) the part where said insulating layer comes in contact with said fringe is made of the same material as said fringe.

16. The method of claim 10, wherein said fringe surrounds said central area around the rim of said central area.

17. The method of claim 10, wherein the width of said fringe is 0.1 mm or 0.2 mm.

18. The method of claim 10, wherein said printed circuit board is a flip chip BGA.
